(19) United States
(12) Patent Application Publication
(10) Pub. No.: US 2006/0029735 A1
(43) Pub. Date: Feb. 9, 2006

(54) Oxidation process apparatus and oxidation process

(76) Inventor: Kyung-Seok Ko, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/143,590

(22) Filed: Jun. 3, 2005

(30) Foreign Application Priority Data
Aug. 4, 2004 (KR) 10-2004-0061441

(51) Int. Cl. C23C 16/00

(52) U.S. Cl. 427/248.1; 118/715

(57) ABSTRACT

Provided is an oxidation process apparatus including a process chamber, a wafer boat loading a plurality of wafers in the process chamber, the wafers are stacked in a plurality of bands, a first gas supply unit supplying a first gas into the process chamber, and a second gas supply unit to supply a second gas to each of the plurality of wafer bands.

### BACKGROUND OF THE INVENTION

1. Field of the Invention

The present invention generally relates to an oxidation process apparatus and an oxidation method. More particularly, the present invention generally relates to an oxidation process apparatus and an oxidation method to form a uniform ultra-thin oxide film.

A claim of priority is made to Korean Patent Application No. 10-2004-0061441 filed on Aug. 4, 2004, the disclosure of which is incorporated herein by reference.

2. Description of the Related Art

Generally, semiconductor integrated circuits are fabricated by performing various processes such as a film forming, etching, oxidation, and diffusion processes on a semiconductor wafer.

Conventional oxidation processes are performed, for example, to form oxidation layers on single-crystal silicon films, polysilicon films, or metal films. In addition, oxidation processes are used to form gate oxide films or insulating films on capacitors.

Depending on the pressure in a process chamber during an oxidation process, a process may be classified as an atmospheric pressure oxidation process or a vacuum pressure oxidation process. The oxidation processes may be further classified as wet oxidizing processes or dry oxidizing processes, depending on the type of oxidation gas used during the oxidation process.

Japanese Patent Unexamined Publication No. 1991-140453 discloses one conventional wet oxidizing process of generating steam by burning hydrogen in an oxygen atmosphere. Japanese Patent Publication No. 1982-001232 discloses another conventional dry oxidizing process by providing only ozone or oxygen in a process chamber.

An oxide film formed by a dry oxidation process has higher dielectric strength, higher corrosion resistance, and better reliability than an oxide film formed by a wet oxidation method. An oxide film formed by an atmospheric pressure oxidation process usually has higher stack rate and better uniformity than an oxide film formed by a vacuum pressure oxidation process. However, an oxide film formed by the vacuum pressure oxidation process has higher uniform intrafilm thickness than an oxide film formed by the atmospheric pressure oxidation process.

Satisfactory oxide film characteristics can be achieved by using the above-mentioned conventional oxidation methods. However, as critical dimensions and thickness of a film decrease, improved oxide film characteristics and better uniform intrafilm thickness are required.

Japanese Patent Unexamined Publication No. 1992-018727, for example, discloses a process of supplying H₂ gas and O₂ gas independently into a vertical type process chamber, and generating steam by igniting H₂ gas in a combustion space. The steam follows the heat of a wafer during an oxidation process.

However, concentration of steam is higher at a lower portion of the process chamber than an upper portion of the process chamber, because steam at the upper portion of the process chamber is consumed during the oxidation process. Accordingly, oxide film uniformity or intrafilm thickness may vary depending on the location of a wafer inside the process chamber.

Japanese Patent Publication No. 1982-001232, discloses another conventional process where O₂ gas or O₂ and H₂ gases are supplied into a vertical type process chamber through a single nozzle onto a plurality of wafers. However, an oxide film is also formed under high pressure. In addition, the direction of the gas flow in an upper portion is different than the direction of the gas flow at a lower portion of the process chamber, therefore, steam concentration throughout the process chamber is substantially different.

U.S. Pat. No. 6,037,273 discloses yet another conventional process, where O₂ gas and H₂ gas are supplied into a process chamber. Stacked wafers and a heater are located within the process chamber. Oxygen and H₂ gases react with each other to produce steam near surface of the wafers. The steam oxidizes the surface of the wafers to form oxide films on the wafers. However, the distance between a gas inlet, which supplies the O₂ and H₂ gases, and the wafers is only 20-30 mm, and the process chamber is under high pressure; as a result, substantial improvement in the uniform intrafilm thickness of the oxide film is not realized.

### SUMMARY OF THE INVENTION

The present invention provides an oxidation process apparatus for forming an ultra-thin oxide film having a uniform thickness.

The oxidation process apparatus includes a process chamber having a top portion, a lower portion, and a sidewall, a wafer boat adapted to hold a plurality of wafers in the process chamber, wherein the wafers are stacked in a plurality of bands, a first gas supply source having a first gas supply pipe adapted to supply a first gas into the process chamber, and a second gas supply source having a plurality of second gas pipes adapted to supply a second gas to each of the plurality of bands.

The present invention also discloses a method of forming an oxide film on a semiconductor wafer using the oxidation process apparatus.

A method of forming an oxide film on a substrate by loading wafers stacked in a plurality of bands into a process chamber, adjusting temperature in the process chamber to a range of between about 800 to 1000° C., and generating oxygen radicals by supplying a first gas into the process chamber through a first gas supply pipe, wherein the first gas supply is disposed above the process chamber, and supplying a second gas through a plurality of second gas supply pipes, and wherein respective ends of the plurality of second supply gas pipes are positioned next to the plurality of bands.

### BRIEF DESCRIPTION OF THE DRAWINGS

The above and other aspects of the present invention will become more apparent by description of the detail preferred embodiments of the present invention with reference to the attached drawings in which:

FIG. 1 is a schematic diagram of an oxidation apparatus according to an embodiment of the present invention;

FIG. 2 is a cross-section of the oxidation apparatus taken along the line C-C′ shown in FIG. 1;

FIG. 3 is a perspective view of a second gas supply line of the oxidation apparatus shown in FIG. 1;

FIG. 4 is a schematic sequence diagram illustrating an oxidation process according to an embodiment of the present invention;

FIG. 5 illustrates an oxide film formed using an oxidation process according to the present invention;

FIGS. 6A through 6C illustrate results of testing uniform thickness of an oxide film formed using the oxidation process according to the embodiment illustrated in FIG. 4;

FIGS. 7A through 7D illustrate results of testing uniform thickness of oxide films formed under different conditions in the oxidation process according to the embodiment illustrated in FIG. 4;

FIGS. 8A through 8D show current-voltage (I-V) graphs and Weibull plots obtained by testing oxide films formed using the oxidation process according to the embodiment illustrated in FIG. 4 for time-zero dielectric breakdown (TZDB); and

FIG. 9 is a schematic diagram of an oxidation apparatus according to another embodiment of the present invention.

### DETAILED DESCRIPTION OF THE INVENTION

Aspects of the present invention will be better understood by reference to the following detailed description of preferred embodiments and the accompanying drawings. The present invention may, however, be embodied in many different forms and should not be construed as being limited to the embodiments set forth herein. Rather, these embodiments are teaching examples. Like reference numerals refer to like elements throughout the specification.

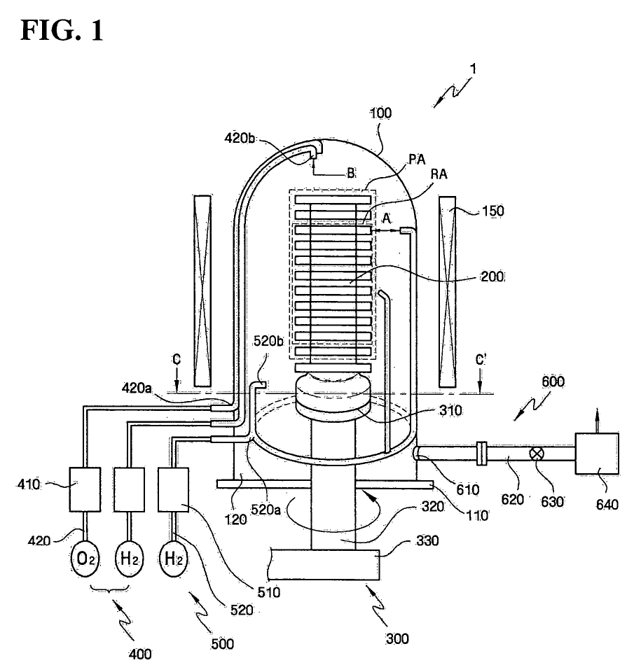

FIG. 1 is a schematic diagram of an oxidation process apparatus according to an embodiment of the present invention.

Referring to FIG. 1, an oxidation process apparatus 1 includes a process chamber 100, a heater 150, a wafer boat 200, a wafer boat rotator 300, a first gas supply source 400, a second gas supply source 500, and a discharging unit 600.

Process chamber 100 may be a vertical or horizontal type. Hereinafter, for description purposes only, process chamber 100 is a vertical type. Process chamber 100 is a single-wall cylindrical structure extending in a vertical direction having a closed dome top. Alternatively, process chamber 100 can be a double-wall structure in which an inner pipe and an outer pipe are separated from each other by a predetermined distance. Process chamber 100 is preferably made of quartz.

A cylindrical shaped manifold 120 preferably made of stainless steel is positioned at a bottom portion of process chamber 100.

A cap 110 is disposed below manifold 120. Cap 110 moves in a vertical direction by the rotation of wafer boat rotator 300. When cap 110 moves up, it closes an opening at the bottom of manifold 120 to hermetically seal process chamber 100.

Wafer boat 200, also generally made of quartz, is adapted to be positioned within process chamber 100. Wafers on which an oxide layer is to be formed are positioned in specific intervals in wafer boat 200. Wafer boat 200 also moves in conjunction with the movement of cap 110.

An area of wafer boat 200 on which oxidation process is performed is referred to as a process area (PA). In addition, dummy wafers may be positioned at the top and bottom of the PA, respectively. Accordingly, an area where fabricated wafers are positioned is referred to as a real process area (RA).

When wafer boat 200 is positioned within process chamber 100, wafer boat 200 is spaced away from the wall of process chamber 100 by a preferable distance.

A heater 150, e.g., a resistance heater, is positioned approximate and outside of process chamber 100. Heater 150 heats the interior of process chamber 100 or wafers positioned therein to a predetermined temperature.

Wafer boat rotator 300 includes a rotary plate 310, a pivot 320, and an arm 330. Wafer boat 200 is attached to rotary plate 310. Rotary plate 310 is positioned above pivot 320. Pivot 320 and cap 110 are sealed by a magnetic fluid seal (not shown). Arm 330 is positioned below pivot 320.

When pivot 320 rotates, rotary plate 310 rotates along with it. As a result, wafer boat 200 positioned above rotary plate 310 moves vertically. During an oxidation process, wafer boat rotator 300 is preferably continuously rotated. Accordingly, an oxide film is uniformly formed on a wafer.

First gas supply line 400 and second gas supply source 500 positioned on manifold 120 penetrate into the interior of process chamber 100. First gas supply source 400 includes a first gas controller 410 and a first gas supply pipe 420. Second gas supply source 500 includes a second gas controller 510 and a supply pipe 520. First and second gas supply source 400 and 500 are preferably made of corrosion-free Teflon®.

First gas supply source 400 supplies an oxidation gas into process chamber 100, but may also supply a reduction gas. The oxidation gas and reduction gas may be supplied together through a single first gas supply pipe 420 or individually supplied through a plurality of first gas supply pipe 420. An oxidation gas is O₂, N₂O, NO, and NO₂. A reduction gas is H₂, NH₂, CH₄, and HCl. To perform an oxidation process according to an embodiment of the present invention, the oxidation gas and reduction gas are supplied into the process chamber to generate oxygen radicals. Hereinafter, for the purpose of explanation, O₂ is used as the oxidation gas and H₂ is used as the reduction gas. First gas supply line 400 serves as the main gas supplier of oxidation process apparatus 1.

In the embodiment of the present invention as shown in FIG. 1, the oxidation gas and reduction gas are separately supplied through a plurality of first gas supply pipes 420, and the flow rates of the oxidation and reduction gases are controlled by first gas controllers 410. First gas supply pipe 420 may have various shape and may supply the gases from the top or bottom of process chamber 100.

Oxidation and reduction gases are supplied from the bottom process chamber 100. First gas supply pipe 420 further includes a leading portion 420a and an end portion 420b. Leading portion 420a is curved near manifold 120. First gas supply pipe 420 runs along a sidewall of process chamber 100.

In addition, end portion 420b may include a shower head. By adapting the shower head at an end point B, the oxidation and reduction gases are supplied to a wider range of area within a short time.

Second gas supply line 500 generally supplies a reduction gas into process chamber 100, but may also supply an oxidation gas. The oxidation and reduction gases may be supplied together through a single second gas supply pipe 520 or may be supplied through a plurality of second gas supply pipe 520. In the embodiment of the present invention, only the reduction gas is supplied through a single second gas supply line 500. The rate at which the reduction gas flows into process chamber 100 is controlled by second gas controller 510. Second gas supply pipe 520 may also have various shapes, and may be position to supply the reduction gas from the top or bottom of process chamber 100. In the embodiment of the present invention, the reduction gas is supplied from the bottom process chamber 100. Second gas supply pipe 520 further includes a leading portion 520a and a plurality of end portions 520b. Leading portion 520a is curved near manifold 120. End portion 520b is separated from wafer boat 200 by a distance A. Distance A is provided to produce a discharge conductance and is set based on a gas flow rate or pressure within process chamber 100. Distance A is preferably set at 100-200 mm.

Locations of the plurality of end portions 520b are determined based on how the wafers are stacked in wafer boat 200. In other words, a plurality of wafers stacked on wafer boat 200 are grouped into a plurality of bands, and end portions 520b are located at respective bands to supply the reduction gas.

When a plurality of wafers is grouped into a plurality of bands, only the RA is considered. The wafers are grouped into a group of 20 through 60 wafers. The bands may be regular or irregular in number. For example, assuming there are 150 wafers stacked on wafer boat 200, and there are 13 dummy wafers at the top and 7 dummy wafers at the bottom, in this situation, 130 wafers in the RA are grouped into 26 wafers of 5 bands. Alternatively, depending on the supply volume of the reduction gas, the 130 wafers may be irregularly grouped into 5 bands of 28, 26, 26, 26, and 24. When the wafers in the RA are numbered from the bottom of wafer boat 200, end portions 520b are respectively positioned at the sides of the 28th, 54th, 80th, 106th, and 130th wafers.

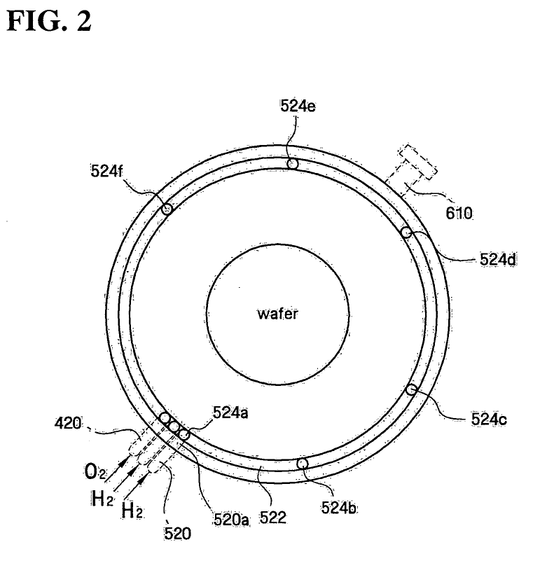

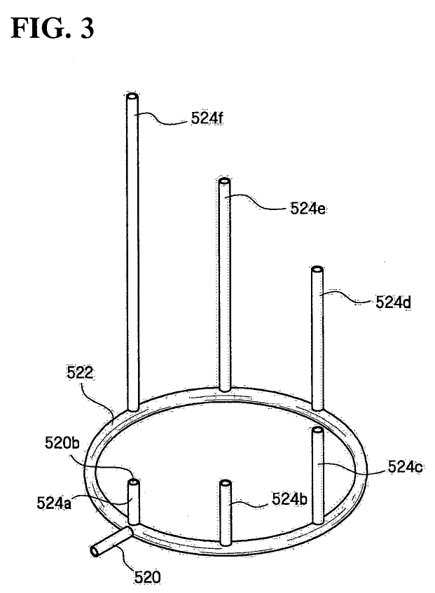

End portions 520b positioned at the respective bands may be aligned (stacked) vertically (not shown). Preferably, the plurality of second gas supply pipe 520 forms a ring around wafer boat 200 (see FIGS. 2 and 3).

When a reduction gas is supplied through second gas supply source 500, the reduction gas is uniformly supplied to the plurality of wafers. As a result, thickness or uniform intrafilm thickness of an oxide film on a particular wafer is consistent regardless of the position of that wafer on wafer boat 200.

A discharging source 600 is preferably positioned at an opposite side of first and second gas supply sources 400 and 500. Discharging source 600 includes an outlet 610, a discharging pipe 620, a combination valve 630, and a vacuum pump 640. Outlet 610 is connected to one end of discharging pipe 620, and vacuum pump 640 is connected to the other end of discharging pipe 620. Combination valve 630 is installed in discharging pipe 620.

To decompress process chamber 100, gases are discharged through discharging pipe 620 by the action of vacuum pump 640. Combination valve 630 closes and opens to control the pressure within process chamber 100.

Although not shown, a nitrogen gas supply line to supply nitrogen gas is disposed at manifold 120 below outlet 610. Nitrogen gas supply line includes a nitrogen gas supply pipe and a nitrogen gas controller.

FIG. 2 is a cross-section of oxidation apparatus 1 taken along a line C-C′ shown in FIG. 1. FIG. 3 is a perspective view of second gas supply line 520 according to the embodiment illustrated in FIG. 1.

Referring to FIGS. 2 and 3, second gas supply pipe 520 is formed in a ring shape to surround stacked wafers. Second gas supply pipe 520 includes a ring portion 522 positioned around the stacked wafers, and first through sixth branches 524a, 524b, 524c, 524d, 524e, 524f arranged along ring portion 522.

The reduction gas supplied into second gas supply pipe 520 flows into branches 524a through 524f via ring portion 522. For example, if 138 wafers among 150 staked wafers are in an RA, and the 138 wafers are evenly grouped into six bands, there are 23 wafers in each band. First branch 524a extends up to a side of the 23rd wafer, the second branch 524b extends up to a side of the 47th wafer, and the third through sixth branches 524c-524f extend up the wafers in a similar manner.

It is preferable that ring portion 522, branches 524a through 524f, and second gas supply pipe 520 are integrally formed with process chamber 100, but may be separately formed and combined with process chamber 100. In the embodiment of the present invention as shown in FIG. 1, because wafer boat 200 may move toward the sidewall of process chamber 100, it is more preferable that ring portion 522 and branches 524a through 524f are closer to the sidewall of process chamber 100 to minimize damage to wafers during an oxidation process.

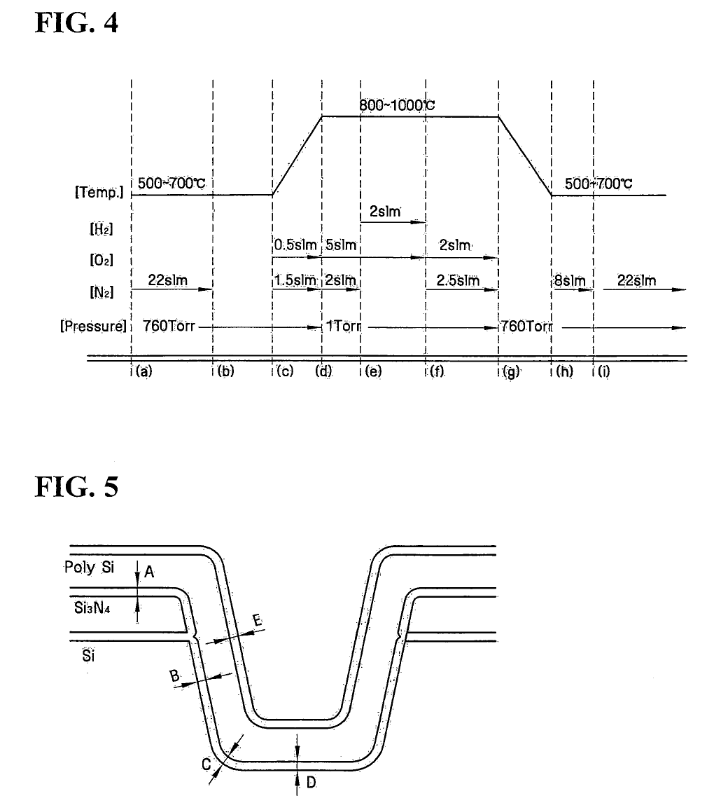

FIG. 4 is a schematic sequence diagram illustrating an oxidation process according to an embodiment of the present invention.

The oxidation process includes loading a wafer boat having a plurality of wafers into a process chamber, supplying reduction gas to each band from a side thereof, and generating oxygen radicals by supplying oxidation gas and reduction gas into process chamber to form an oxide film on the wafers.

In stage (a), wafers are stacked into a wafer boat 200, and then wafer boat 200 is loaded within a process chamber 100. A wafer boat rotator 300 rotates pivot 320, which in turn rotates a rotary plate 310. As a result, a cap 110 along with wafer boat 200 vertically moves up and hermetically seals process chamber 100. Nitrogen gas is introduced into chamber process 100 at a flow rate of 22 standard liters per minute (slm), and in addition, concentration of O₂ within process chamber 100 is continuously monitored. Process chamber 100 is maintained at an internal temperature between about 500-700° C. and an internal pressure between about 750-770 Torr. Preferably, process chamber 100 is maintained at an internal temperature of about 600° C. and an internal pressure of about 760 Torr.

In stage (b), the pressure within process chamber 100 is gradually lowered. Wafers may be damaged if large amount of gas is discharged at one time. Therefore, the gas is slowly discharged through a plurality of steps, known as “slow pumping.” Specifically, N₂ gas is discharged out of process chamber 100 by opening a valve 630 and through the action of vacuum pump 640. The internal pressure is preferably lowered a two step process.

In stage (c), an oxidation atmosphere is formed within process chamber 100. As O₂ and N₂ gases are supplied at flow rates of 0.5 slm and 1.5 slm, respectively, the internal temperature of process chamber 100 is increased at a rate of about 23-28° C./min to reach 800-1000° C.

In addition, the internal pressure is rapidly lowered. In other words, after the internal pressure of process chamber 100 is lowered through the slow pumping process, it is preferably lowered by a two step main pumping process. The internal pressure of process chamber 100 is lowered below 1 Torr (i.e., 133 Pa). It is preferable that the internal pressure range is between about 0.05 Torr (i.e., 6.7 Pa) to 0.5 Torr (i.e., 67 Pa)

In stage (d), the internal temperature and pressure of process chamber 100 are adjusted for the last time prior to an oxidation process. In detail, possible leakage and the internal temperature of process chamber 100 are checked, and process chamber 100 is adjusted to an appropriate internal pressure by main pumping and through the supply of N₂ gas. Nitrogen gas is supplied at a flow rate of about 2 slm. Oxygen gas is supplied at a flow rate of about 5 slm.

In stage (e), the oxidation process is performed. The temperature and pressure formed through the previous stages are maintained. When process chamber 100 reaches an oxygen atmosphere, H₂ gas is supplied at a flow rate of 2 slm into process chamber 100 to generate oxygen radials. Hydrogen gas is supplied through a second gas supply line 500 to a plurality of bands into which the stacked wafers are grouped. Accordingly, thickness or uniform intrafilm thickness of an oxide film on a wafer is uniform regardless of the position of the wafer on wafer boat 200. The oxidation process is selectively performed while the wafers are rotated by the rotation of rotary plate 310.

Oxygen radicals are generated in process chamber 100 through a combustion reaction described below. In the chemical formulae, an asterisk “*” denotes a radical.
H₂+O₂→H*+HO₂
O₂+H*→OH*+O*
H₂+O*→H*+OH*
H*+OH*→H*+H₂O

When H₂ gas and O₂ gases are supplied into process chamber 100, combustion of H₂ gas and O₂ gas generates oxygen radicals O*, hydroxide radicals OH*, and steam. Oxygen radicals O* and hydroxide radicals OH* are useful in the improvements of the uniform intrafilm thickness of an oxide film. The O* radicals and OH* are highly reactive; therefore, they react before reaching an oxygen-silicon interface. Accordingly, an oxygen layer can be effectively cured. In other words, drawbacks such as Si—Si bonds, Si dangling bonds, or strained Si—O bonds that deteriorate wafer reliability are prevented, thereby improving an interface layer between Si and SiO₂. As the concentration of hydrogen increases, the amount of oxygen radicals increases, thereby improving the oxide layer.

In addition, since the oxidation process is performed under vacuum pressure much lower than the conventional oxidation process, chemical reactions expressed by the above chemical formulae gradually occurs more readily. Accordingly, an appropriate amount of H₂O, O*, and OH* are supplied to a wafer regardless of its positions on wafer boat 200. The wafers are uniformly oxidized, and consequently a uniform intrafilm thickness of an oxide film is also increased.

The uniform intrafilm thickness is enhanced by supplying H₂ gas through second gas supply source 500. As described above, the wafers stacked on wafer boat 200 are grouped into 20-60 wafers per band, and second gas supply pipe 520 individually supplies reduction gas to the individual bands.

During the process of the present invention, oxidation or/and reduction gases are supplied into process chamber 100 through first gas supply source 400 by a shower method, and a reduction gas is uniformally supplied onto the stacked wafers through second gas supply line 500. Accordingly, oxygen radicals are not too rapidly consumed by the wafers, and the oxygen radicals are not concentrated at a particular area in process chamber 100. Therefore, oxide films formed on the individual wafers exhibit good stack rate and uniformity. In addition, an oxidation reaction is performed without the oxygen radicals having to move the entire height of process chamber 100.

Moreover, an oxide film is uniformly formed on each wafer from a periphery edge to a center to improve intrafilm thickness uniformity and characteristics of the oxide film. Additional improvements are achieved by rotating wafer boat 200.

In stage (f), the oxygen radicals and hydrogen radicals are purged from process chamber 100. A plurality of purges are performed, and preferably, at least two purges are performed. The internal pressure of process chamber 100 is slowly lowered, O₂ gas is lowered to a flow rate of 2 slm and N₂ gas is lowered to a flow rate of 2.5 slm.

In stage (g), the internal temperature of process chamber 100 is lowered, and the internal pressure thereof is also lowered to complete the oxidation process. The internal pressure is slowly increased by supplying N₂ to prevent back pressure. The internal temperature of process chamber 100 is lowered to a range of about 500-700° C., and preferably, maintained at about 600° C.

In stage (h), atmospheric pressure is formed by supplying N₂ gas at a flow rate of 8 slm. As in stage (f), the internal pressure is slowly decreased preferably by a two step process. When the internal pressure is sufficiently increased to prevent back pressure, the pressure is increased up to about 760 Torr.

In stage (i), the oxidation process is finished. In detail, rotary plate 310 is stopped, and wafer boat 200 is taken out of process chamber 100. During stage (i), N₂ gas is continuously supplied into process chamber 100 at a flow rate of 22 slm.

Hereinafter, an oxide film formed using the oxidation process according to the embodiment illustrated in FIG. 4 will be compared with an oxide film formed according a conventional oxidation process. In addition, the characteristics of the oxide film formed using the oxidation process according to the embodiment illustrated in FIG. 4 will be described.

Table 1 shows a thickness comparison between an oxide film formed according to the oxidation process according to the present invention illustrated in FIG. 4 and an oxide film formed according a conventional oxidation process.

TABLE 1

| Present | Conditions | | Thickness | A (on Si₃N₄) | 13 |
|---|---|---|---|---|---|
| invention | Temperature(° C.) | 950 | (nm) | B (Wall) | 16.5 |
| | Pressure (Pa) | 40.3 | | C (Corner) | 11.5 |
| | Time (min) | 42 | | D (Bottom) | 16 |
| | H₂ concentration (%) | 19.8 | | E (on Poly Si) | 16 |
| | O₂ (sccm) | 2000 | Ratio | A/D | 0.81 |
| | H₂ (sccm) | 494 | | B/D | 1.03 |
| | N₂ (sccm) | — | | | |
| Conventional | Conditions | | Thickness | A (on Si₃N₄) | 1.7 |
| | Temperature (° C.) | 950 | (nm) | B (Wall) | 26 |
| | Pressure (Pa) | ATM | | C (Corner) | 13.5 |
| | Time (min) | 8.5 | | D (Bottom) | 16 |
| | H₂ concentration (%) | 11.5 | | E (on Poly Si) | 15.5 |
| | O₂ (sccm) | 3000 | Ratio | A/D | 0.106 |
| | H₂ (sccm) | 3000 | | B/D | 1.625 |
| | N₂ (sccm) | 20000 | | | |

The oxidation process according to the present invention was performed at a temperature of about 950° C.; pressure of about 40.3 Pa; H₂ gas concentration of about 19.8%; O₂ gas flow rate of about 2000 sccm; and H₂ gas flow rate of about 494 sccm. These conditions correspond to stage (e) of FIG. 4.

The conventional oxidation process was performed at a temperature of about 950° C.; ATM pressure; H₂ gas concentration of about 11.5%; O₂ gas flow rate of about 3000 sccm; H₂ gas flow rate of about 3000 sccm; and N₂ gas flow rate of about 20000 sccm.

First, the characteristics of the oxide film formed according to the present invention will be described. Referring to FIG. 5, “A” denotes a thickness of an oxide film formed on a Si₃N₄ layer. “B” denotes a thickness of an oxide film formed on a wall of a trench. “C” denotes a thickness of an oxide film formed on a corner of the trench. “D” denotes a thickness of an oxide film formed on a bottom of the trench. “E” denotes a thickness of an oxide film formed on a poly silicon layer.

The thickness of an oxide film can be measured using transmission electron microscopy (TEM). The TEM performs measurement in units of 10 Å using electrons and is especially useful in viewing a grating structure and defects.

An A/D ratio indicates a ratio of the thickness of the oxide film on the Si3N4 layer to the thickness of the oxide film on the bottom of the trench. A B/D ratio indicates a ratio of the thickness of the oxide film on the wall of the trench to the thickness of the oxide film on the bottom of the trench.

With the present invention, the B/D ratio was 1.03, which means that thickness of B and D are almost the same. However, with the conventional oxidation process, the B/D ratio was 1.625, which means that B is much thicker than D.

When a trench is oxidized, a growth rate at a (100) surface is different from that at a (111) surface, therefore, the oxide layer is thicker on the wall of the trench than on other portions. However, when oxygen radical is used, due to its reactivity, a uniform growth rate is realized regardless of the structure of the trench. Accordingly, with the present invention, the B/D ratio has a uniform value of 1.03.

When critical dimensions and film thickness are noticeably decreased, it is desirable for walls to be thin and uniform. Accordingly, the present invention is more effective than the conventional oxidation process.

Further, when oxygen radical is used, the A/D ratio is 0.81. It is generally known that about 23 Å of Si3N4 is oxidized when 50 Å of Si is oxidized. Accordingly, an oxidizing power is about 46% with respect to Si. However, with the conventional oxidation process, the A/D ratio is 0.106, which means that the oxide film was insufficiently formed on the Si3N4 layer.

Table 2 shows a composition comparison between the oxide film formed by the oxidation process according to the present invention and the oxide film formed according the conventional oxidation process.

TABLE 2

| | O(%) | C(%) | Si(%) | O/Si |
|---|---|---|---|---|
| Present invention (Thickness: 30 Å) | 72.1 | 2.8 | 25.1 | 2.87 |
| Present invention (Thickness: 35 Å) | 71.4 | 2.7 | 25.9 | 2.76 |
| Present invention (Thickness: 43 Å) | 71.4 | 1.8 | 26.8 | 2.66 |
| Conventional method (Thickness: 43 Å) | 70.9 | 1.9 | 27.1 | 2.61 |

Composition of a layer can be measured using X-ray photoelectron spectroscopy (XPS). The XPS performs measurement in units of 10-100 Å. The XPS can analyze all elements. Since an energy level is determined based on kinetic energy of photoelectrons, the XPS is useful in analyzing chemical bonds and elements.

Referring to Table 2, when oxygen radicals were used according to the process of the present invention, a ratio of O to Si decreased as the thickness of the oxide film increased. In addition, when the thickness of the oxide film was 43 Å, proportions of Si were 26.8% in the present invention and 27.1% in the conventional method. The results were similar regardless of whether oxygen radicals were used.

In other characteristics, although not shown in the tables, surface roughness at the same thickness of the oxide film was better with the present invention than with the conventional process.

In addition, an activation energy was about 0.23 eV in equipment (using 200 mm wafers) used in the present invention while it was about 1.52 eV in a conventional oxidation method. Accordingly, it can be inferred that oxygen radical is reactive.

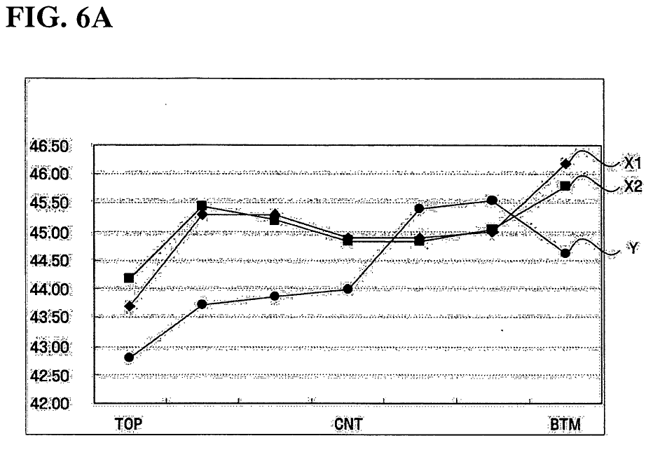

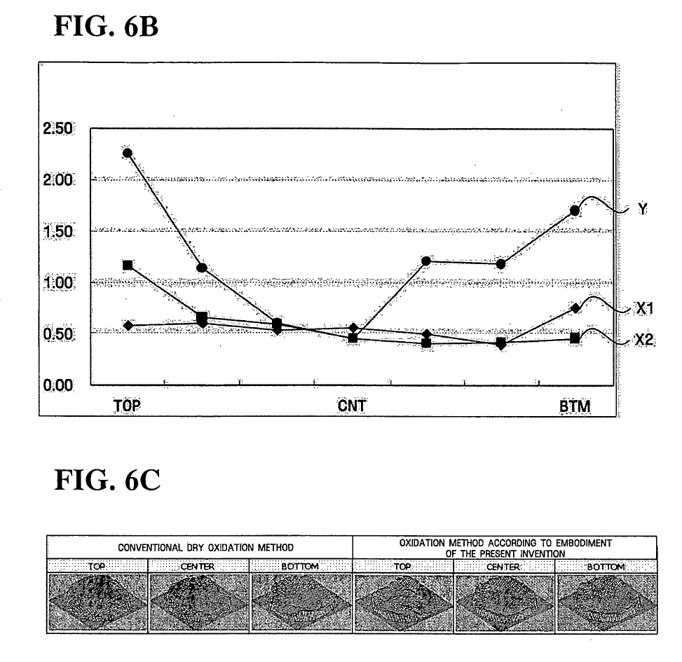

FIGS. 6A through 6C illustrate the result of testing uniform thickness of an oxide film formed using the oxidation process according to the embodiment illustrated in FIG. 4. FIGS. 6A through 6C, X1 refers to the case where 10 and 5 dummy wafers were disposed at a top and bottom, respectively, in wafer boat 200. X2 refers to the case where 13 and 2 dummy wafers were disposed at the top and bottom, respectively, in wafer boat 200.

FIG. 6A illustrates thicknesses of oxide films formed on wafers positioned at the top, center (CNT), and bottom (BTM) of wafer boat 200 at a temperature of about 800° C. Oxide films X1 and X2 formed according to the present invention did not deviate from a target thickness of 45 Å. However, oxide films Y formed according to the conventional oxidation process deviated about 2 Å or greater from the target thickness at the top of wafer boat 200, and did not reach the target thickness at the center of wafer boat 200.

Referring to FIG. 6B, oxide films Y formed according to the conventional oxidation process varied in a range of 1.5 Å or more at the top and bottom of wafer boat 200. However, oxide films X1 and X2 formed according to the present invention varied at a range in the vicinity of 0.5 Å.

FIG. 6C illustrates computer graphics of oxide films formed according to the conventional oxidation process and the embodiment of the present invention. In the present invention, the oxide films are less curved and are more stable.

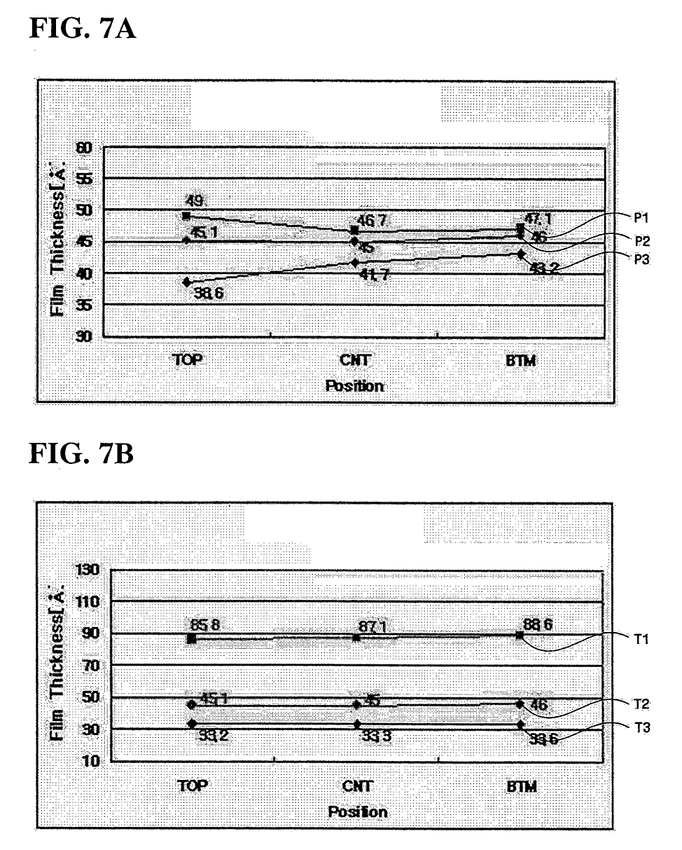

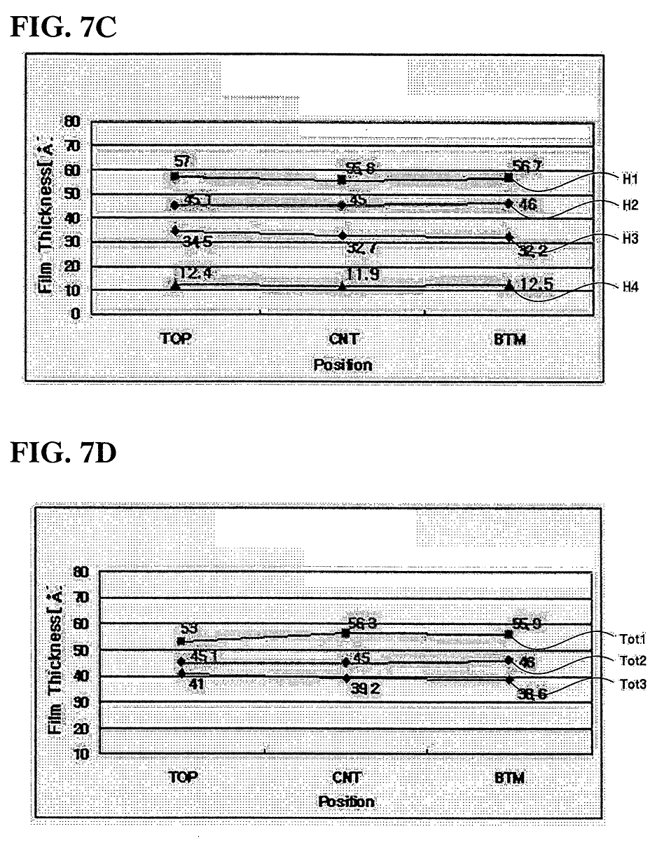

FIGS. 7A through 7D illustrate results of testing uniformity thickness of oxide films formed under different conditions using the oxidation process according to the embodiment illustrated in FIG. 4.

Referring to FIG. 7A, a thickness of an oxide film changes in accordance with the internal pressure of process chamber 100. In detail, a test was performed where the internal pressures were 30 Pa (P1), 54 Pa (P2), and 70 Pa (P3), however, the internal temperature and processing time were the same for each case, the thickness of an oxide film increased as the internal pressure increased.

Referring to FIG. 7B, the thickness of an oxide film changed in accordance with the processing time. In detail, in comparison with experiments where the processing times were 48 minutes (T1), 12 minutes and 30 seconds (T2), and 6 minutes (T3), respectively, and the internal temperature and pressure were the same for each experiment, the thickness of an oxide film increased as the process time increased.

Referring to FIG. 7C, the thickness of an oxide film changed in accordance with the concentration of H₂ gas within process chamber 100. In detail, in comparison with experiments where gas flow rates were 0 slm (H4), 90 slm (H3), 180 slm (H2), and 360 slm (H1), respectively, and the internal temperature, internal pressure, and processing time were the same for each experiment, the thickness of an oxide film increased as the H₂ gas concentration increased.

Referring to FIG. 7D, the thickness of an oxide film changed in accordance with the concentration of gas within process chamber 100. In detail, in comparison with experiments having gas flow rates of 1215 slm (Tot3), 1430 slm (Tot2), and 4860 slm (Tot1), respectively, and the internal temperature, internal pressure, and processing time were the same for each experiment, the thickness of an oxide film increased as the concentration of gas increased.

Table 3 shows results of time-zero dielectric breakdown (TZDB) for oxide films formed using the oxidation process according to the embodiment illustrated in FIG. 4.

TABLE 3

| | | | AVG | AVG FLD | |
|---|---|---|---|---|---|
| Division | Lot | Region | BV (V) | (MV/cm) | Extrinsic (%) |
| Conventional | L1 | PERI | 5.95 | 9.92 | 0 |
| oxidation | | 32 M Cell | 11.57 | 19.28 | |
| method | | PERI | 5.65 | 9.42 | 1.47 |
| | | 32 M Cell | 11.17 | 18.61 | |
| | L2 | PERI | 5.90 | 9.83 | 0 |
| | | 32 M Cell | 9.94 | 16.56 | |
| | | PERI | 5.63 | 9.39 | 0 |
| | | 32 M Cell | 10.96 | 18.27 | |
| Oxidation | L3 | PERI | 6.16 | 10.26 | 0 |
| method | | 32 M Cell | 10.99 | 18.31 | |
| according to the | | PERI | 5.63 | 9.39 | 1.47 |
| present | | 32 M Cell | 11.05 | 18.42 | |
| invention | L4 | PERI | 6.16 | 10.26 | 0 |
| | | 32 M Cell | 10.91 | 18.19 | |
| | | PERI | 5.63 | 9.38 | 1.47 |
| | | 32 M Cell | 10.81 | 18.02 | |

A TZDB characteristic was evaluated as follows. Oxide films L1 and L2 were formed on two wafers, respectively, using the conventional oxidation process. Oxide films L3 and L4 were formed on two different wafers, respectively, using the oxidation process according to the present invention. A circuit was formed on each of the wafers. When a voltage supplied to a gate electrode of each circuit was increased, current flowing to the circuit was measured.

An average breakdown voltage (AVG BV) was measured at a current of 10 μA, and converted into an average field (AVG FLD). At that time, an extrinsic failure rate was evaluated.

Oxide films L3 and L4 according to the present invention have similar characteristics compared to conventional oxide films L1 and L2. In detail, the oxide films have similar AVG BV and AVG FLD and a similar extrinsic failure rate ranging from 0 to 1.47%.

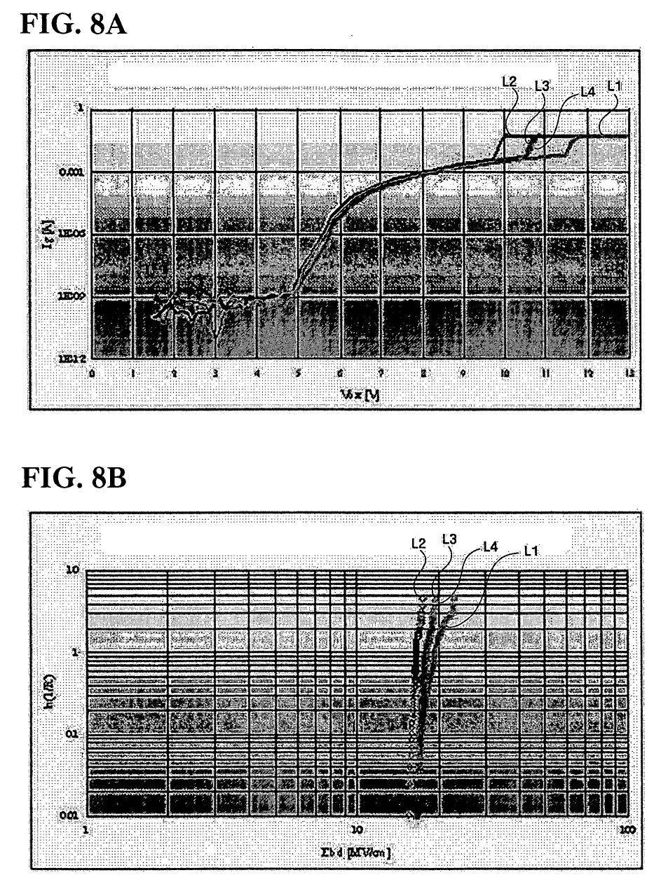

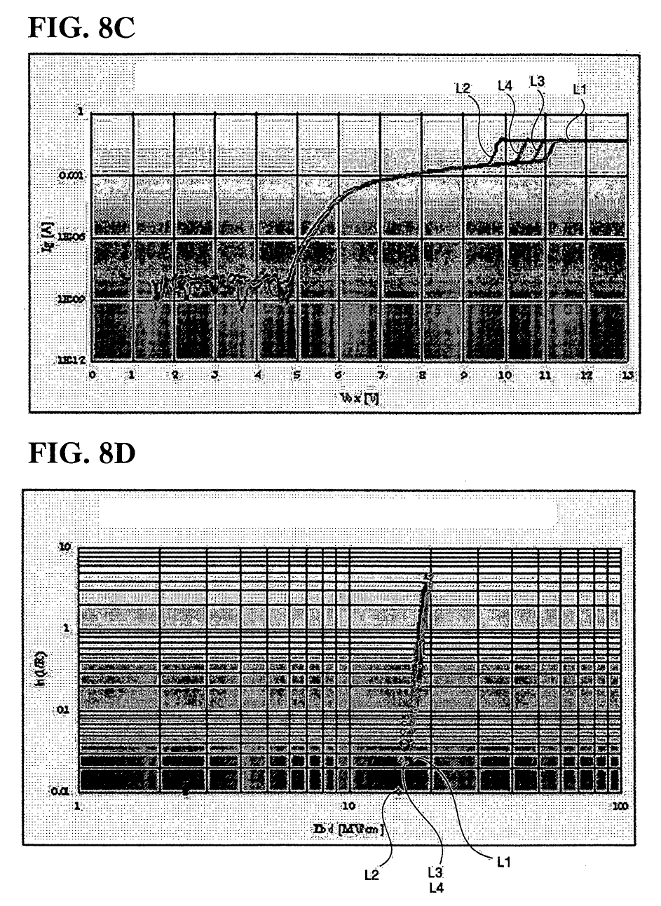

FIGS. 8A through 8D are current-voltage (I-V) graphs and Weibull plots obtained by testing oxide films L1, L2, L3, and L4 formed using the conventional oxidation process and using the oxidation process according to the embodiment illustrated in FIG. 4 for TZDB. FIGS. 8A through 8D are graphs formed based on Table 3.

FIG. 8A is an I-V graph illustrating results of evaluating PERI arrays, and FIG. 8B is a Weibull plot illustrating results of evaluating the PERI arrays.

Referring to FIG. 8A, curves corresponding to oxide films L1 through L4 have similar shapes. In terms of a dielectric breakdown voltage, oxide films L3 and L4 are between oxide films L1 and L2.

Referring to FIG. 8B, oxide films L1 through L4 have similar characteristics, as shown in FIG. 8A.

FIG. 8C is an I-V graph illustrating results of evaluating memory arrays, and FIG. 8D is a Weibull plot illustrating results of evaluating the memory arrays.

Referring to FIG. 8C, curves corresponding to oxide films L1 through L4 nearly overlap each other. In terms of a dielectric breakdown voltage, oxide films L3 and L4 are positioned between oxide films L1 and L2.

Referring to FIG. 8D, oxide films L1 through L4 have similar characteristics, as shown in FIG. 8C.

Accordingly, it can be inferred that oxide films L3 and L4 formed using the oxidation process according to the present invention have similar reliability as oxide layers L1 and L2 formed using the conventional oxidation process.

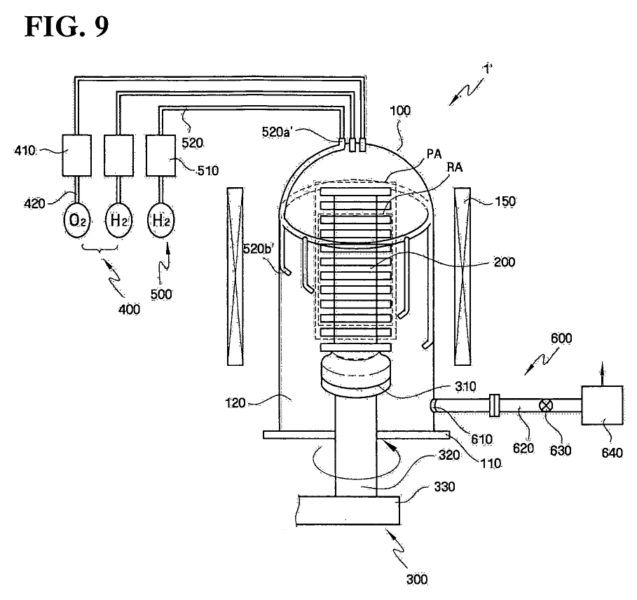

FIG. 9 is a schematic diagram of an oxidation apparatus 1′ according to another embodiment of the present invention. A first gas supply source 400 and a second gas supply source 500 supply gases from a top of process chamber 100. Like reference numerals in FIGS. 1 and 9 denote like elements, and descriptions thereof are omitted.

Referring to FIG. 9, oxidation apparatus 1′ includes a process chamber 100, a heater 150, a wafer boat 200, a wafer boat rotator 300, a first gas supply source 400, a second gas supply source 500, and a discharging unit 600.

First gas supply source 400 and second gas supply source 500 both penetrate into the interior from the top of process chamber 100. First gas supply source 400 supplies an oxidation gas, and second gas supply source 500 supplies a reduction gas. As described for the first embodiment, first gas supply source 400 may also supply the reduction gas, and second gas supply source 500 may also supply the oxidation gas.

Locations of end portions 520b′ of second gas supply source 500 are determined based on wafers stacked on wafer boat 200 disposed within process chamber 100. In other words, a plurality of wafers stacked on wafer boat 200 are grouped into a plurality of bands, and end portions 520b′ are positioned at the respective bands to supply the reduction gas. Accordingly, second gas supply pipe 500 includes a single leading portion 520a′ and a plurality of end portions 520b′.

While the present invention has been particularly shown and described through exemplary embodiments thereof with reference to the accompanying drawings, it will be understood by those of ordinary skill in the art that various changes in form and details may be made therein without departing from scope of the present invention. The exemplary embodiments are described as working examples

What is claimed is:

1. An oxidation process apparatus, comprising:
a process chamber having a top portion, a lower portion, and a sidewall;
a wafer boat adapted to hold a plurality of wafers in the process chamber, wherein the wafers are stacked in a plurality of bands;
a first gas supply source having a first gas supply pipe adapted to supply a first gas into the process chamber; and
a second gas supply source having a plurality of second supply gas pipes adapted to supply a second gas to each of the plurality of bands.

2. The apparatus of claim 1, wherein the first gas supply source supplies the first gas and second gas.

3. The apparatus of claim 2, wherein the first and second gases are supplied separate first gas supply pipes.

4. The apparatus of claim 1, wherein the second gas supply source supplies the first gas and the second gas.

5. The apparatus of claim 1, wherein the first gas is an oxidation gas, and the second gas is a reduction gas.

6. The apparatus of claim 1, wherein the first gas pipe extends from the first gas supply source at the bottom of the process chamber, extends along the sidewall, and is adapted to supply the first gas from the top of the process chamber.

7. The apparatus of claim 1, wherein the first gas pipe extends from the first gas supply source at the top of the process chamber, and is adapted to supply the first gas from the top of the process chamber.

8. The apparatus of claim 7, wherein the plurality of second supply gas pipes surround the plurality of wafers, and wherein respective ends of the plurality of second supply gas pipes are positioned next to the plurality of bands.

9. The apparatus of claim 1, wherein the first gas supply source comprises a shower head.

10. The apparatus of claim 1, further comprising:
a vacuum pump adapted to create vacuum pressure in the process chamber; and
a heater adapted to heat the process chamber or the wafers.

11. The apparatus of claim 1, further comprising a rotator connected to an end of the wafer boat and adapted to rotate the wafer boat.

12. A method of forming an oxide film on a substrate, comprising:
loading wafers stacked in a plurality of bands into a process chamber;
adjusting temperature in the process chamber to a range of between about 800 to 1000° C.; and
generating oxygen radicals by supplying a first gas into the process chamber through a first gas supply pipe, wherein the first gas supply pipe is disposed above the process chamber, and supplying a second gas through a plurality of second gas supply pipes, and wherein respective ends of the plurality of second gas supply pipes are positioned next to the plurality of bands.

13. The method of claim 12, wherein the plurality of wafers are stacked in a vertical direction.

14. The method of claim 12, wherein the first gas is an oxidation gas selected from the group consisting of O₂, NO₂O, NO, NO₂, and mixture thereof.

15. The method of claim 12, wherein the second gas is reduction gas selected from the group consisting of H₂, NH₂, CH₄, HCl, and mixture thereof.

16. The method of claim 12, further comprising:
after loading the plurality of wafers, supplying nitrogen gas into the process chamber at a flow rate of about 22 standard liters per minute (slm), maintaining the process chamber temperature in a range between of about 500-700° C., and an internal pressure in a range between of about 750-770 torr;
lowering the pressure in the process chamber;
supplying the first gas into the process chamber at a flow rate of about 0.5 slm, lowering the flow rate of the nitrogen gas to about 1.5 slm, and increasing the process chamber temperature to a range between of about 800-1000° C.;
supplying the second gas at a flow rate about 2 slm, and increasing the flow rate of the first gas to about 5 slm;
increasing the pressure of the process chamber to about 760 torr, stopping the flow of the first and second gases, increasing the flow rate of nitrogen gas to about 8 slm, and decreasing the temperature of the process chamber to a range between of about 500-700° C.; and
removing the plurality of wafers from the process chamber.

17. The method of claim 16, wherein the plurality of wafers is rotated during the oxidation process.
